(19) United States
(12) Patent Application Publication
(10) Pub. No.: US 2024/0274768 A1
(43) Pub. Date: Aug. 15, 2024

(54) DISPLAY SUBSTRATE, METHOD FOR FORMING THE SAME AND DISPLAY DEVICE

(71) Applicant: BOE TECHNOLOGY GROUP CO., LTD., Beijing (CN)

(72) Inventors: Shuang Sun, Beijing (CN); Fangzhen Zhang, Beijing (CN); Jing Niu, Beijing (CN)

(73) Assignee: BOE TECHNOLOGY GROUP CO., LTD., Beijing (CN)

(21) Appl. No.: 18/023,443

(22) PCT Filed: May 24, 2022
(86) PCT No.: PCT/CN2022/094653

§ 371 Date: Feb. 27, 2023

(51) Int. Cl. H01L 33/62; H01L 25/075; H01L 33/54

(52) U.S. Cl. CPC H01L 33/62; H01L 25/0753; H01L 33/54; H01L 2933/005; H01L 2933/0066

(57) ABSTRACT

A display substrate includes: a base substrate, a display functional layer located on a first side surface of the base substrate, where the display functional layer includes an encapsulation layer, and a plurality of metal lines located on a second side surface of the base substrate, a first gap being provided between adjacent metal lines. A first orthographic projection of the encapsulation layer onto the base substrate at least partially does not overlap a second orthographic projection of the first gap onto the base substrate, and/or, a light-shielding layer is arranged at a side of the encapsulation layer facing the metal lines, the light-shielding layer is located on the first side surface of the base substrate, and a third orthographic projection of the light-shielding layer onto the base substrate at least partially overlaps the second orthographic projection.

### TECHNICAL FIELD

The present disclosure relates to the field of display technology, in particular to a display substrate, a method for forming the display substrate and a display device.

### BACKGROUND

In order to realize a large screen display, a plurality of small-sized display screens needs to be spliced. Lines are arranged on a back surface of the display screen and connected to lines on a front surface of the display screen at a side surface of the display screen so as to realize the display.

Metal lines on the back surface of the display screen are usually made of an alloy of CuTi and patterned by laser etching. When a metal on the back surface of the display screen is etched by using a laser, a display functional layer inside the display substrate is exposed to the laser, and then damaged, thereby adversely affecting the yield of the display substrate.

### SUMMARY

An object of the present disclosure is to provide a display substrate, a method for forming the display substrate and a display device, so as to improve the yield of the display substrate.

In order to realize the above-mentioned object, technical solutions in the embodiments of the present disclosure are as follows.

In one aspect, a display substrate is provided, including: a base substrate, a display functional layer located on a first side surface of the base substrate, where the display functional layer includes an encapsulation layer, and a plurality of metal lines located on a second side surface of the base substrate, a first gap being provided between adjacent metal lines, and the first side surface being opposite to the second side surface. A first orthographic projection of the encapsulation layer onto the base substrate and a second orthographic projection of the first gap onto the base substrate at least partially do not overlap each other, and/or, a light-shielding layer is arranged at a side of the encapsulation layer facing the metal lines, the light-shielding layer is located on the first side surface of the base substrate, and a third orthographic projection of the light-shielding layer onto the base substrate at least partially overlaps the second orthographic projection.

In some embodiments of the present disclosure, the third orthographic projection fully coincides with the second orthographic projection.

In some embodiments of the present disclosure, the light-shielding layer and a gate metal layer of the display functional layer are arranged at a same layer and made of a same material.

In some embodiments of the present disclosure, the encapsulation layer includes a plurality of hollowed-out regions, and the second orthographic projection falls within a fourth orthographic projection of each hollowed-out region onto the base substrate.

In some embodiments of the present disclosure, the fourth orthographic projection does not overlap an orthographic projection of a metal layer on the first side surface of the base substrate onto the base substrate.

In some embodiments of the present disclosure, the metal lines are fan-out area lines, a line width of each metal line is 60 μm to 80 μm, and a spacing between adjacent metal lines is 27 μm to 47 μm.

In some embodiments of the present disclosure, the display substrate includes: a buffer layer located on the first side surface of the base substrate, a gate insulation layer located at one side of the buffer layer away from the base substrate, an interlayer insulation layer located at one side of the gate insulation layer away from the base substrate, a planarization layer located at one side of the interlayer insulation layer away from the base substrate, a passivation layer located at one side of the planarization layer away from the base substrate, the encapsulation layer located at one side of the passivation layer away from the base substrate, and a light-emitting element located at one side of the encapsulation layer away from the base substrate.

In some embodiments of the present disclosure, the light-emitting element of the display substrate is a Mini LED or a Micro LED.

In some embodiments of the present disclosure, the base substrate is transparent.

In some embodiments of the present disclosure, each metal line is connected to a signal line of the display functional layer through a lead on a side surface of the base substrate, or each metal line is connected to a signal line of the display functional layer through a via hole penetrating the base substrate.

The present disclosure further provides in some embodiments a display device, including the above-mentioned display substrate.

The present disclosure further provides in some embodiments a method for forming a display substrate, including: providing a base substrate, forming a display functional layer on a first side surface of the base substrate, where the display functional layer includes an encapsulation layer, forming a plurality of metal lines on a second side surface of the base substrate, a first gap being provided between adjacent metal lines, and the first side surface being opposite to the second side surface. A first orthographic projection of the encapsulation layer onto the base substrate and a second orthographic projection of the first gap on the base substrate at least partially do not overlap each other, and/or, a light-shielding layer is formed at a side of the encapsulation layer facing the metal lines, the light-shielding layer is located on the first side surface of the base substrate, and a third orthographic projection of the light-shielding layer onto the base substrate at least partially overlaps the second orthographic projection.

In some embodiments of the present disclosure, the light-shielding layer and a gate metal layer of the display functional layer are formed through a single patterning process.

In some embodiments of the present disclosure, the forming the encapsulation layer includes: etching the encapsulation layer to form a plurality of hollowed-out regions, where the second orthographic projection falls within a fourth orthographic projection of each hollowed-out region onto the base substrate.

The embodiments of the present disclosure have the following beneficial effects.

In the above scheme, the first orthographic projection of the encapsulation layer onto the base substrate and the second orthographic projection of the first gap onto the base substrate at least partially do not overlap each other, so that when etching is performed by using a laser to form the metal lines on the second side surface of the base substrate, it is able to reduce the adverse effect of the laser on the encapsulation layer, avoid such a case where bubbling occurs in the encapsulation layer causing the encapsulation layer to be damaged, and improve the yield of the display substrate. In addition, the light-shielding layer is further arranged at the side of the encapsulation layer facing the metal lines, and the third orthographic projection of the light-shielding layer onto the base substrate at least partially overlaps the second orthographic projection, so it is able to prevent the encapsulation layer from being irradiated by the laser, avoid such a case where bubbling occurs in the encapsulation layer causing the encapsulation layer to be damaged, and improve the yield of the display substrate.

### BRIEF DESCRIPTION OF THE DRAWINGS

FIG. 1 is a schematic view showing the layout of metal lines on a second side surface of a display substrate.

FIG. 2 and FIG. 3 are each a sectional view of a display substrate in the related art along line AA.

FIG. 4-FIG. 8 are each a sectional view of a display substrate according to one embodiment of the present disclosure along line AA.

### REFERENCE SIGN LIST

01 metal line
02 base substrate
03 buffer layer
04 gate insulation layer
05 interlayer insulation layer
06 planarization layer
07 passivation layer
08 signal line
09 encapsulation layer
091 damaged area
092 hollowed-out region

### DETAILED DESCRIPTION

In order to make the technical problems, technical solutions, and advantages of the present disclosure more apparent, the present disclosure will be described hereinafter in a clear and complete manner in conjunction with the drawings and embodiments.

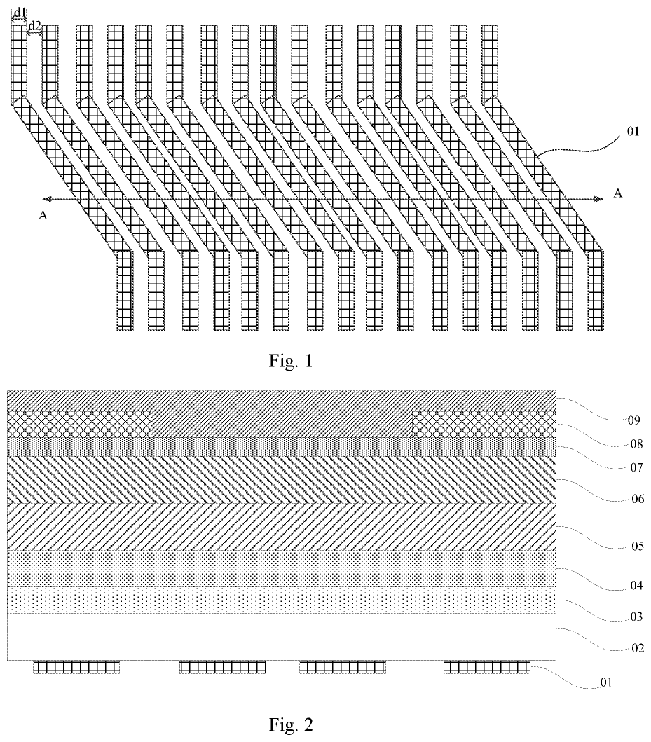

In order to realize a large screen display, a plurality of display substrates needs to be spliced together. As shown in FIG. 1, a plurality of metal lines 01 is arranged on a second side surface of a display substrate, where the metal lines 01 are fan-out area lines, and is connected to signal lines in a display functional layer on a first side surface of the display substrate at a side surface of the display substrate. When forming the metal lines, a metal layer may be formed on the second side surface of the display substrate, the metal layer may be an alloy of CuTi, and the formed metal layer is etched by using a laser to form the metal lines 01.

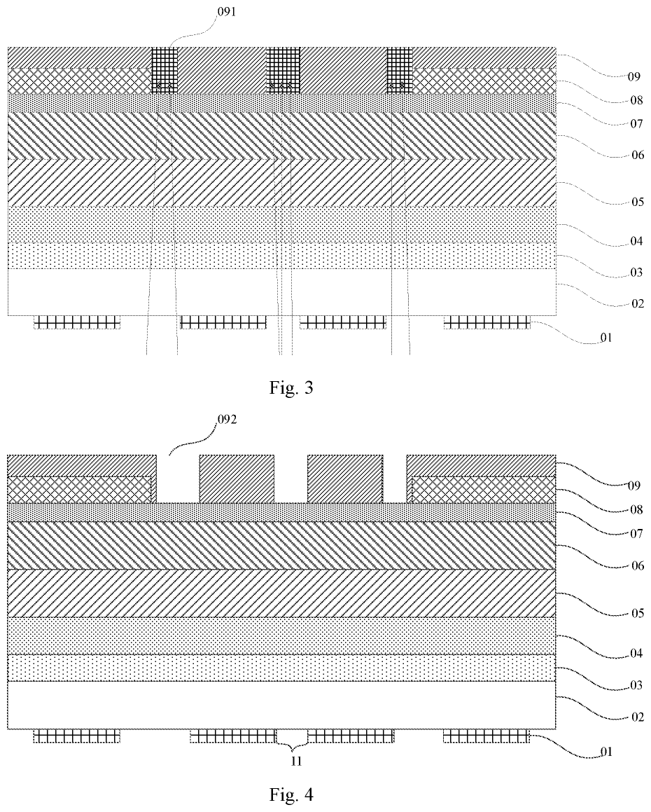

FIG. 2 is a sectional view of the display substrate in FIG. 1 along line AA. As shown in FIG. 2, the display functional layer is arranged on the first side surface of the display substrate, and the display functional layer includes a buffer layer 03, a gate insulation layer 04, an interlayer insulation layer 05, a planarization layer 06, a passivation layer 07, a signal line 08, an encapsulation layer 09, and the like. The encapsulation layer 09 serves as a planarization layer, is made of a photosensitive material such as polyimide, or a photoresist. When etching the metal layer by using a laser, an interior of the display substrate is exposed to the laser after the laser passes through the base substrate 01, and then the display functional layer is exposed to the laser. As shown in FIG. 3, the encapsulation layer 09 is sensitive to light and may absorb the laser, so that the encapsulation layer 09 is damaged, e.g., bubbling occurs in the encapsulation layer 09, and a damaged region 091 appears, thereby adversely affecting the yield of the display substrate.

The present disclosure provides in some embodiments a display substrate, a method for forming the display substrate, and a display device, so as to improve the yield of the display substrate.

The present disclosure provides in some embodiments a display substrate, including: a base substrate, a display functional layer located on a first side surface of the base substrate, where the display functional layer includes an encapsulation layer, and a plurality of metal lines located on a second side surface of the base substrate, a first gap being provided between adjacent metal lines, and the first side surface being opposite to the second side surface. A first orthographic projection of the encapsulation layer onto the base substrate and a second orthographic projection of the first gap onto the base substrate at least partially do not overlap each other, and/or, a light-shielding layer is arranged at a side of the encapsulation layer facing the metal lines, the light-shielding layer is located on the first side surface of the base substrate, and a third orthographic projection of the light-shielding layer onto the base substrate at least partially overlaps the second orthographic projection.

In the embodiment of the present disclosure, the base substrate may be a glass substrate or a quartz substrate, and the base substrate is transparent. Therefore, when etching is performed by using a laser to form the metal lines on the second side surface of the base substrate, the laser passes through the base substrate, to cause the first side surface of the base substrate to be exposed to the laser.

The first orthographic projection of the encapsulation layer onto the base substrate and the second orthographic projection of the first gap onto the base substrate at least partially do not overlap each other, so that when etching is performed by using a laser to form the metal lines on the second side surface of the base substrate, it is able to reduce the adverse effect of the laser on the encapsulation layer, avoid such a case where bubbling occurs in the encapsulation layer causing the encapsulation layer to be damaged, and improve the yield of the display substrate. In addition, the light-shielding layer is further arranged at the side of the encapsulation layer facing the metal lines, and the third orthographic projection of the light-shielding layer onto the base substrate at least partially overlaps the second orthographic projection, so it is able to prevent the encapsulation layer from being irradiated by the laser, avoid such a case where bubbling occurs in the encapsulation layer causing the encapsulation layer to be damaged, and improve the yield of the display substrate.

In a specific embodiment of the present disclosure, as shown in FIG. 4, metal lines 01 are arranged on the second side surface of the display substrate and a first gap 11 is provided between adjacent metal lines 01. The display functional layer is arranged on the first side surface of the display substrate, and the display functional layer includes a display electrode, a driving thin film transistor, a switch thin film transistor, and the like, which are composed of such film layers as a buffer layer 03, a gate insulation layer 04, an interlayer insulation layer 05, a planarization layer 06, a passivation layer 07, a signal line 08, and an encapsulation layer 09, and a light-emitting element. The encapsulation layer 09 serves as a planarization layer and functions as to insulate the signal line 08 from other conductive film layers.

In order to prevent the encapsulation layer 09 from being exposed to the laser and then being damaged when etching the metal layer on the second side surface of the display substrate by using a laser, the encapsulation layer 09 may be processed to remove at least part of the encapsulation layer 09 directly facing the first gap 11, an orthographic projection of the encapsulation layer 09 directly facing the first gap 11 onto the base substrate 02 falls within the second orthographic projection of the first gap 11 onto the base substrate 02. A part of, or all of, the encapsulation layer 09 directly facing the first gap 11 may be removed, or, after all of the encapsulation layer 09 directly facing the first gap 11 is removed, an additional part of the encapsulation layer 09 may be further removed without affecting the functionality of the encapsulation layer 09. As shown in FIG. 4, a part of the encapsulation layer 09 is removed, the encapsulation layer including a hollowed-out region 092 is formed, and a fourth orthographic projection of the hollowed-out region 092 onto the base substrate 02 at least partially overlaps the second orthographic projection, preferably, the second orthographic projection falls within the fourth orthographic projection of the hollowed-out region 092 onto the base substrate 02.

In a region where the signal line 08 is located, the signal line 08 is able to shield the laser light, so as to prevent the encapsulation layer 09 from being exposed to the laser. In addition, it requires the encapsulation layer 09 to cover the signal line 08, so it is unnecessary to remove the encapsulation layer 09 in the region where the signal line 08 is located, as long as it is ensured that the second orthographic projection falls within the fourth orthographic projection of the hollowed-out region 092 onto the base substrate 02 in a region where the signal line 08 is not arranged. In this way, it is able to ensure that the encapsulation layer 09 is not exposed to the laser after the laser passes through the first gap, that is, either there is no encapsulation layer 09 in a traveling path of the laser, or the laser is shielded by the signal line 08, thereby to avoid such a case where bubbling occurs in the encapsulation layer causing the encapsulation layer 09 to be damaged.

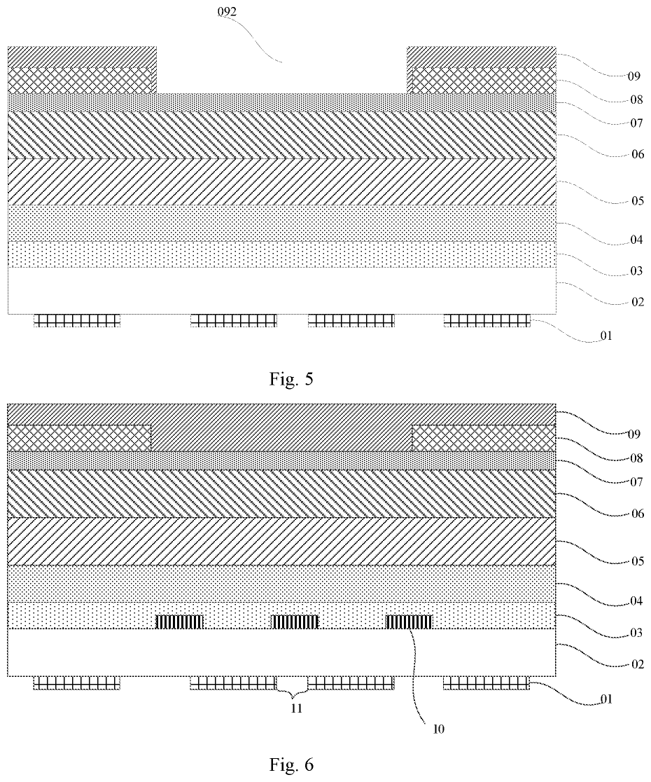

In some embodiments of the present disclosure, as shown in FIG. 5, the photosensitive material 09 may be removed in the region where the signal line 08 is not arranged, so as to greatly reduce the probability of bubbling in the encapsulation layer 09.

In some embodiments of the present disclosure, the fourth orthographic projection does not overlap an orthographic projection of the metal layer on the first side surface of the base substrate onto the base substrate, i.e., in a region where the metal layer is not arranged, only transparent insulation film layers such as a buffer layer 03, a gate insulation layer 04, an interlayer insulation layer 05, a planarization layer 06, a passivation layer 07 are on the first side surface of the base substrate. Since it is unable for these film layers to block the laser, and the encapsulation layer 09 in the above-mentioned region is removed, so as to prevent the encapsulation layer 09 from being exposed to the laser.

In another specific embodiment of the present disclosure, as shown in FIG. 6, the metal lines 01 are arranged on the second side surface of the display substrate and the first gap 11 is provided between adjacent metal lines 01. The display functional layer is arranged on the first side surface of the display substrate, and the display functional layer includes a display electrode, a driving thin film transistor, a switch thin film transistor, and the like, which are composed of such film layers as a buffer layer 03, a gate insulation layer 04, an interlayer insulation layer 05, a planarization layer 06, a passivation layer 07, a signal line 08, and an encapsulation layer 09. The encapsulation layer 09 serves as a planarization layer and functions as to insulate the signal line 08 from other conductive film layers.

In order to prevent the encapsulation layer 09 from being exposed to the laser and being damaged when etching the metal layer on the second side surface of the display substrate by using a laser, a light-shielding layer 10 is arranged at the side of the encapsulation layer 09 facing the metal lines 11, the light-shielding layer 10 is able to block the laser, so as to prevent the encapsulation layer 09 from being exposed to the laser after the laser passes through the first gap 11, thereby to avoid such a case where bubbling occurs in the encapsulation layer causing the encapsulation layer to be damaged.

As long as the light-shielding layer 10 is located between the encapsulation layer 09 and the metal lines 11, the light-shielding layer 10 may be located between the passivation layer 07 and the planarization layer 06, between the planarization layer 06 and the interlayer insulation layer 05, between the interlayer insulation layer 05 and the gate insulation layer 04, between the gate insulation layer 04 and the buffer layer 03, or between the buffer layer 03 and the base substrate 02.

The closer the light-shielding layer 10 is to the metal traces 11, the better the light-shielding effect. While preventing the encapsulation layer 09 from being exposed to the laser, the light-shielding layer 10 also shields the laser, so as to prevent other film layers of the display functional layer from being exposed to the laser and then being damaged. Preferably, as shown in FIG. 6, the light-shielding layer 10 is located between the buffer layer 03 and the base substrate 02, so that the light-shielding layer 10 also prevent the gate insulation layer 04, the interlayer insulation layer 05, the passivation layer 07, and the planarization layer 06 from being exposed to the laser, thereby to prevent the gate insulation layer 04, the interlayer insulation layer 05, the passivation layer 07 and the planarization layer 06 from being damaged by the laser.

The third orthographic projection of the light-shielding layer 10 onto the base substrate 02 at least partially overlaps the second orthographic projection of the first gap 11 onto the base substrate 02. Preferably, the third orthographic projection of the light-shielding layer 10 onto the base substrate 02 fully coincides with the second orthographic projection of the first gap 11 on the base substrate 02, so that the light-shielding layer 10 is able to fully shield light passing through the first gap 11 that enters the display functional layer. The third orthographic projection of the light-shielding layer 10 onto the base substrate 02 may further exceed the second orthographic projection of the first gap 11 onto the base substrate 02. However, in order to reduce the adverse effect of the light-shielding layer 10 on the light-transmittance of the display substrate, an area of the light-shielding layer 10 should not be too large.

In addition, since the signal line 08 is able to block the laser to prevent the encapsulation layer 09 from being exposed to the laser in the region where the signal line 08 is arranged, the light-shielding layer 10 may be not arranged in the region where the signal line 08 is arranged, i.e., the orthographic projection of the light-shielding layer 10 onto the base substrate does not overlap the orthographic projection of the signal line 08 onto the base substrate.

In the embodiment of the present disclosure, an additional film layer may be arranged on the display substrate to form the light-shielding layer 10, or an existing film layer of the display substrate may be used to form the light-shielding layer 10 without the additional film layer. The light-shielding layer 10 may be made of a metal or a non-metal material. A source/drain metal layer or a gate metal layer of the display substrate may be used to form the light-shielding layer, i.e., the light-shielding layer and the gate metal layer or the source/drain metal layer of the display functional layer are arranged at a same layer and made of a same material. In some embodiments of the present disclosure, the light-emitting element of the display substrate is a micro LED or a mini LED. A driving current of the LED is relatively high, and a driving thin film transistor in a pixel driving circuit is usually a double-gate thin film transistor. The double-gate thin film transistor includes a top gate metal layer and a bottom gate metal layer, and the bottom gate metal layer of the display substrate close to the base substrate may be used to form the light-shielding layer, so it is able to form patterns of the light-shielding layer 10 and a bottom gate electrode of the thin film transistor through a single patterning process, thereby to save the quantity of patterning processes.

In the embodiment of the present disclosure, the light-shielding layer 10 may be an entire layer, so as to simplify the manufacturing process. However, in order to prevent the light-shielding layer 10 from blocking an alignment mark on the display substrate, the light-shielding layer 10 may be patterned, so that a shape of the light-shielding layer 10 matches the first gap 11, and the orthographic projection of the light-shielding layer 10 onto the base substrate coincides with the orthographic projection of the first gap onto the base substrate. In this way, the light-shielding layer 10 does not block the alignment mark on the display substrate while shielding the laser.

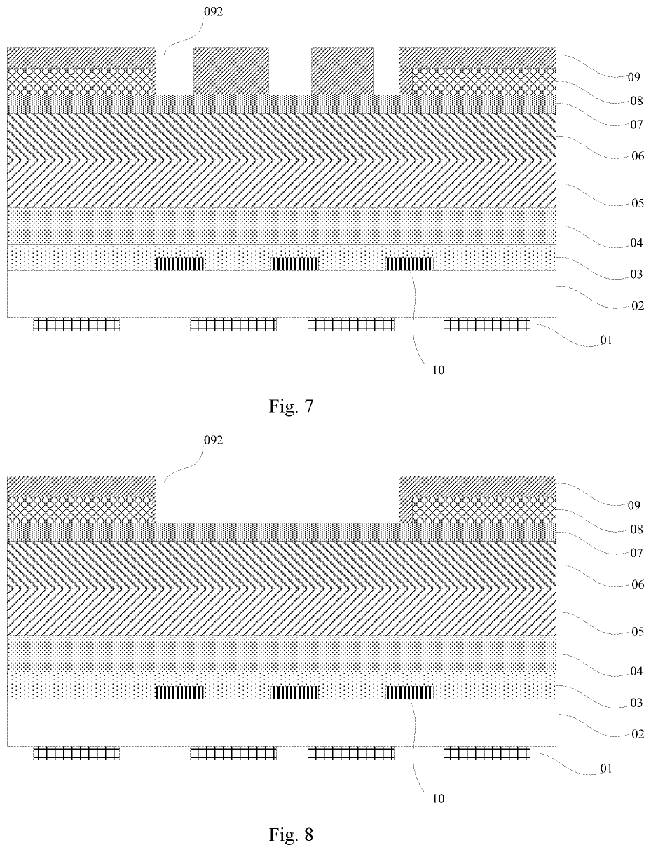

In some embodiments of the present disclosure, as shown in FIG. 7, the encapsulation layer 09 is processed on the first side surface of the display substrate to remove at least part of the encapsulation layer 09 directly facing the first gap 11, and the light-shielding layer 10 is added on the display substrate, so, by providing the hollowed-out region 092 and the light-shielding layer 10, it is able to prevent the encapsulation layer 09 from be exposed to the laser after passing through the first gap 11, thereby to avoid such a case where bubbling occurs in the encapsulation layer causing the encapsulation layer 09 to be damaged.

In some embodiments of the present disclosure, as shown in FIG. 8, all the photosensitive materials 09 may be removed in the region where the signal line 08 is not arranged, and the light-shielding layer 10 is added on the display substrate, so, by providing the hollowed-out region 092 and the light-shielding layer 10, it is able to prevent the encapsulation layer 09 from be exposed to the laser after passing through the first gap 11, thereby to avoid such a case where bubbling occurs in the encapsulation layer causing the encapsulation layer 09 to be damaged.

In the embodiment of the present disclosure, the metal lines are formed on the second side surface of the base substrate, and may be, but not limited to, fan-out area lines. The metal lines may also be other lines required to be arranged on the second side surface of the base substrate. As shown in FIG. 1, each metal line 11 has a line width d1 of 60 μm to 80 μm, such as 70 μm, and a spacing d2 between adjacent metal lines 11 is 27 μm to 47 μm, such as 37 μm. When forming the hollowed-out region of the encapsulation layer 09, a size of the hollowed-out region 092 needs to be determined in accordance with a size of each metal line 11 and the spacing between the metal lines 11, so as to enable the hollowed-out region 092 to directly face the spacing between the metal lines 11.

When the metal lines 11 are the fan-out area lines, the metal lines 11 are relatively dense. When etching the encapsulation layer 09 to form the hollowed-out region 092, the requirement on an etching accuracy is relatively high. In order to reduce the requirement on the etching accuracy, the encapsulation layer 09 may be all removed in the region where the signal line 08 is not arranged, so that an area of the formed hollowed-out region 092 is relatively large, thereby to reduce the requirement on the etching accuracy.

In the embodiment of the present disclosure, the light-emitting element of the display substrate may be a micro light emitting diode (Micro LED), and the display substrate may be a Micro LED display substrate.

The Micro LED display substrate is usually a small-sized display substrate, and when a large-screen display is required, a plurality of small-sized Micro LED display substrates may be spliced together, metal lines 11 are arranged on a back surface of the Micro LED display substrate, and the metal lines are connected to signal lines of the display functional layer through leads on a side surface of the base substrate, or, the metal lines are connected to the signal lines in the display function layer through via holes penetrating the base substrate. The display substrate is not limited to the Micro LED display substrate, and may be other types of display substrates, such as a mini light emitting diode (Mini LED) display substrate or an OLED display substrate, and the technical solution of the present embodiment is applicable to a display scheme where metal lines are arranged on both sides of the display substrate. Typically, a size of a Mini LED is about 100 μm to 300 μm and a size of a Micro LED is below 100 μm.

The present disclosure further provides in some embodiments a display device, including the above-mentioned display substrate.

The display device includes, but not limited to, such components as a radio frequency unit, a network module, an audio outputting unit, an input unit, a sensor, a display unit, a user input unit, an interface unit, a memory, a processor, a power supply. As can be appreciated by the skilled in the art that the structure of the display apparatus does not constitute a limitation to the display device. The display device may include more or fewer components, or some components may be combined, or there may be a different component layout. In some embodiments of the present disclosure, the display device includes, but not limited to, a display, a cellphone, a tablet computer, a television, a wearable device, a navigation display device and so on.

The display device may be any product or member having a display function, e.g., television, display, digital photo frame, mobile phone or flat-panel computer. The display device may further include a flexible circuit board, a printed circuit board and a back plate.

The present disclosure further provides in some embodiments a method for forming a display substrate, including: providing a base substrate, forming a display functional layer on a first side surface of the base substrate, where the display functional layer includes an encapsulation layer, forming a plurality of metal lines on a second side surface of the base substrate, a first gap being provided between adjacent metal lines, and the first side surface being opposite to the second side surface. A first orthographic projection of the encapsulation layer onto the base substrate and a second orthographic projection of the first gap onto the base substrate at least partially do not overlap each other, and/or, a light-shielding layer is formed at a side of the encapsulation layer facing the metal lines, the light-shielding layer is located on the first side surface of the base substrate, and a third orthographic projection of the light-shielding layer onto the base substrate at least partially overlaps the second orthographic projection.

In the embodiment of the present disclosure, the base substrate may be a glass substrate or a quartz substrate, and the base substrate is transparent. Therefore, when etching is performed by using a laser to form the metal lines on the second side surface of the base substrate, the laser passes through the base substrate, to cause the first side surface of the base substrate to be exposed to the laser. The first orthographic projection of the encapsulation layer onto the base substrate and the second orthographic projection of the first gap onto the base substrate at least partially do not overlap each other, so that when etching is performed by using a laser to form the metal lines on the second side surface of the base substrate, it is able to reduce the adverse effect of the laser on the encapsulation layer, avoid such a case where bubbling occurs in the encapsulation layer causing the encapsulation layer to be damaged, and improve the yield of the display substrate. In addition, the light-shielding layer is further arranged at the side of the encapsulation layer facing the metal lines, and the third orthographic projection of the light-shielding layer onto the base substrate at least partially overlaps the second orthographic projection, so it is able to prevent the encapsulation layer from being irradiated by the laser, avoid such a case where bubbling occurs in the encapsulation layer causing the encapsulation layer to be damaged, and improve the yield of the display substrate.

In a specific embodiment of the present disclosure, as shown in FIG. 4, metal lines 01 are arranged on the second side surface of the display substrate and a first gap 11 is provided between adjacent metal lines 01. The display functional layer is arranged on the first side surface of the display substrate, and the display functional layer includes a display electrode, a driving thin film transistor, a switch thin film transistor, and the like, which are composed of such film layers as a buffer layer 03, a gate insulation layer 04, an interlayer insulation layer 05, a planarization layer 06, a passivation layer 07, a signal line 08 and an encapsulation layer 09. The encapsulation layer 09 serves as a planarization layer and functions as to insulate the signal line 08 from other conductive film layers.

In order to prevent the encapsulation layer 09 from being exposed to the laser and then being damaged when etching the metal layer on the second side surface of the display substrate by using a laser, the encapsulation layer 09 may be processed to remove at least part of the encapsulation layer 09 directly facing the first gap 11, an orthographic projection of the encapsulation layer 09 directly facing the first gap 11 onto the base substrate 02 falls within the second orthographic projection of the first gap 11 onto the base substrate 02. A part of, or all of, the encapsulation layer 09 directly facing the first gap 11 may be removed, or, after all of the encapsulation layer 09 directly facing the first gap 11 is removed, an additional part of the encapsulation layer 09 may be further removed without affecting the functionality of the encapsulation layer 09.

In some embodiments of the present disclosure, as shown in FIG. 4, the forming the encapsulation layer 09 includes etching the encapsulation layer to form a plurality of hollowed-out regions 092, where a fourth orthographic projection of each hollowed-out region 092 onto the base substrate 02 at least partially overlaps the second orthographic projection, and preferably, the second orthographic projection falls within the fourth orthographic projection of each hollowed-out region 092 onto the base substrate 02.

In a region where the signal line 08 is located, the signal line 08 is able to shield the laser light, so as to prevent the encapsulation layer 09 from being exposed to the laser. In addition, it requires the encapsulation layer 09 to cover the signal line 08, so it is unnecessary to remove the encapsulation layer 09 in the region where the signal line 08 is located, as long as it is ensured that the second orthographic projection falls into the fourth orthographic projection of the hollowed-out region 092 onto the base substrate 02 in a region where the signal line 08 is not arranged. In this way, it is able to ensure that the encapsulation layer 09 is not exposed to the laser after the laser passes through the first gap, that is, either there is no encapsulation layer 09 in a traveling path of the laser, or the laser is shielded by the signal line 08, thereby to avoid such a case where bubbling occurs in the encapsulation layer causing the encapsulation layer 09 to be damaged.

In some embodiments of the present disclosure, as shown in FIG. 5, the photosensitive material 09 may be removed in the region where the signal line 08 is not arranged, so as to greatly reduce the probability of bubbling in the encapsulation layer 09.

In some embodiments of the present disclosure, the fourth orthographic projection does not overlap an orthographic projection of the metal layer on the first side surface of the base substrate onto the base substrate, i.e., in a region where the metal layer is not arranged, only transparent insulation film layers such as a buffer layer 03, a gate insulation layer 04, an interlayer insulation layer 05, a planarization layer 06, a passivation layer 07 are on the first side surface of the base substrate. Since it is unable for these film layers to block the laser, and the encapsulation layer 09 in the above-mentioned region is removed, so as to prevent the encapsulation layer 09 from being exposed to the laser.

In another specific embodiment of the present disclosure, as shown in FIG. 6, the metal lines 01 are arranged on the second side surface of the display substrate and the first gap 11 is provided between adjacent metal lines 01. The display functional layer is arranged on the first side surface of the display substrate, and the display functional layer includes a display electrode, a driving thin film transistor, a switch thin film transistor, and the like, which are composed of such film layers as a buffer layer 03, a gate insulation layer 04, an interlayer insulation layer 05, a planarization layer 06, a passivation layer 07, a signal line 08, and an encapsulation layer 09. The encapsulation layer 09 serves as a planarization layer and functions as to insulate the signal line 08 from other conductive film layers.

In order to prevent the encapsulation layer 09 from being exposed to the laser and being damaged when etching the metal layer on the second side surface of the display substrate by using a laser, a light-shielding layer 10 is arranged at the side of the encapsulation layer 09 facing the metal lines 11, the light-shielding layer 10 is able to block the laser, so as to prevent the encapsulation layer 09 from being exposed to the laser after the laser passes through the first gap 11, thereby to avoid such a case where bubbling occurs in the encapsulation layer causing the encapsulation layer to be damaged.

As long as the light-shielding layer 10 is located between the encapsulation layer 09 and the metal lines 11, the light-shielding layer 10 may be located between the passivation layer 07 and the planarization layer 06, between the planarization layer 06 and the interlayer insulation layer 05, between the interlayer insulation layer 05 and the gate insulation layer 04, between the gate insulation layer 04 and the buffer layer 03, or between the buffer layer 03 and the base substrate 02.

The closer the light-shielding layer 10 is to the metal traces 11, the better the light-shielding effect. While preventing the encapsulation layer 09 from being exposed to the laser, the light-shielding layer 10 also shields the laser, so as to prevent other film layers of the display functional layer from being exposed to the laser and then being damaged. Preferably, as shown in FIG. 6, the light-shielding layer 10 is located between the buffer layer 03 and the base substrate 02, so that the light-shielding layer 10 also prevent the gate insulation layer 04, the interlayer insulation layer 05, the passivation layer 07, and the planarization layer 06 from being exposed to the laser, thereby to prevent the gate insulation layer 04, the interlayer insulation layer 05, the passivation layer 07 and the planarization layer 06 from being damaged by the laser.

The third orthographic projection of the light-shielding layer 10 onto the base substrate 02 at least partially overlaps the second orthographic projection of the first gap 11 onto the base substrate 02. Preferably, the third orthographic projection of the light-shielding layer 10 onto the base substrate 02 fully coincides with the second orthographic projection of the first gap 11 on the base substrate 02, so that the light-shielding layer 10 is able to fully shield light passing through the first gap 11 that enters the display functional layer. The third orthographic projection of the light-shielding layer 10 onto the base substrate 02 may further exceed the second orthographic projection of the first gap 11 onto the base substrate 02. However, in order to reduce the adverse effect of the light-shielding layer 10 on the light-transmittance of the display substrate, an area of the light-shielding layer 10 should not be too large.

In addition, since the signal line 08 is able to block the laser to prevent the encapsulation layer 09 from being exposed to the laser in the region where the signal line 08 is arranged, the light-shielding layer 10 may be not arranged in the region where the signal line 08 is arranged, i.e., the orthographic projection of the light-shielding layer 10 onto the base substrate does not overlap the orthographic projection of the signal line 08 onto the base substrate.

In the embodiment of the present disclosure, an additional film layer may be arranged on the display substrate to form the light-shielding layer 10, or an existing film layer of the display substrate may be used to form the light-shielding layer 10 without the additional film layer. A source/drain metal layer or a gate metal layer of the display substrate may be used to form the light-shielding layer, i.e., the light-shielding layer and the gate metal layer or the source/drain metal layer of the display functional layer are arranged at a same layer and made of a same material. For example, the light-shielding layer and the gate metal layer of the display functional layer may be formed through a single patterning process. In some embodiments of the present disclosure, a thin film transistor of the display substrate is usually of a double-gate structure, and a bottom gate metal layer of the display substrate close to the base substrate may be used to form the light-shielding layer, so it is able to form patterns of the light-shielding layer 10 and a bottom gate electrode of the thin film transistor through a single patterning process.

In the embodiment of the present disclosure, the metal lines are formed on the second side surface of the base substrate, and may be, but not limited to, fan-out area lines. The metal lines may also be other lines required to be arranged on the second side surface of the base substrate. As shown in FIG. 1, each metal line 11 has a line width d1 of 60 μm to 80 μm, such as 70 μm, and a spacing d2 between adjacent metal lines 11 is 27 μm to 47 μm, such as 37 μm. When forming the hollowed-out region of the encapsulation layer 09, a size of the hollowed-out region 092 needs to be determined in accordance with a size of each metal line 11 and the spacing between the metal lines 11, so as to enable the hollowed-out region 092 to directly face the spacing between the metal lines 11.

When the metal lines 11 are the fan-out area lines, the metal lines 11 are relatively dense. When etching the encapsulation layer 09 to form the hollowed-out region 092, the requirement on an etching accuracy is relatively high. In order to reduce the requirement on the etching accuracy, the encapsulation layer 09 may be all removed in the region where the signal line 08 is not arranged, so that an area of the formed hollowed-out region 092 is relatively large, thereby to reduce the requirement on the etching accuracy.

In the embodiment of the present disclosure, the light-emitting element of the display substrate may be a micro light emitting diode (Micro LED), and the display substrate may be a Micro LED display substrate.

The Micro LED display substrate is usually a small-sized display substrate, and when a large-screen display is required, a plurality of small-sized Micro LED display substrates may be spliced together, metal lines 11 are arranged on a back surface of the Micro LED display substrate, and the metal lines are connected to signal lines of the display functional layer through leads on a side surface of the base substrate, or, the metal lines are connected to the signal lines in the display function layer through via holes penetrating the base substrate. The display substrate is not limited to the Micro LED display substrate, and may be other types of display substrates, such as a mini light emitting diode (Mini LED) display substrate or an OLED display substrate, and the technical solution of the present embodiment is applicable to a display scheme where metal lines are arranged on both sides of the display substrate. Typically, a size of a Mini LED is about 100 μm to 300 μm and a size of a Micro LED is below 100 μm. In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above are merely specific embodiments of the present disclosure, but a scope of the present disclosure is not limited thereto. Any modifications or replacements that would easily occurred to a person skilled in the art, without departing from the technical scope disclosed in the disclosure, should be encompassed in the scope of the present disclosure. Therefore, the scope of the present disclosure shall be subject to the scope defined by the appended claims.

1. A display substrate, comprising:
a base substrate;
a display functional layer located on a first side surface of the base substrate, wherein the display functional layer comprises an encapsulation layer; and
a plurality of metal lines located on a second side surface of the base substrate, a first gap being provided between adjacent metal lines, and the first side surface being opposite to the second side surface,
wherein a first orthographic projection of the encapsulation layer onto the base substrate and a second orthographic projection of the first gap onto the base substrate at least partially do not overlap each other, and/or, a light-shielding layer is arranged at a side of the encapsulation layer facing the metal lines, the light-shielding layer is located on the first side surface of the base substrate, and a third orthographic projection of the light-shielding layer onto the base substrate at least partially overlaps the second orthographic projection.

2. The display substrate according to claim 1, wherein the third orthographic projection fully coincides with the second orthographic projection.

3. The display substrate according to claim 1, wherein the light-shielding layer and a gate metal layer of the display functional layer are arranged at a same layer and made of a same material.

4. The display substrate according to claim 1, wherein the encapsulation layer comprises a plurality of hollowed-out regions, and the second orthographic projection falls within a fourth orthographic projection of each hollowed-out region onto the base substrate.

5. The display substrate according to claim 4, wherein the fourth orthographic projection does not overlap an orthographic projection of a metal layer on the first side surface of the base substrate onto the base substrate.

6. The display substrate according to claim 1, wherein the metal lines are fan-out area lines, a line width of each metal line is 60 μm to 80 μm, and a spacing between adjacent metal lines is 27 μm to 47 μm.

7. The display substrate according to claim 1, wherein the display substrate comprises:
a buffer layer located on the first side surface of the base substrate;
a gate insulation layer located at one side of the buffer layer away from the base substrate;
an interlayer insulation layer located at one side of the gate insulation layer away from the base substrate;
a planarization layer located at one side of the interlayer insulation layer away from the base substrate;
a passivation layer located at one side of the planarization layer away from the base substrate;
the encapsulation layer located at one side of the passivation layer away from the base substrate; and
a light-emitting element located at one side of the encapsulation layer away from the base substrate.

8. The display substrate according to claim 7, wherein the light-emitting element of the display substrate is a mini LED or a micro LED.

9. The display substrate according to claim 1, wherein the base substrate is transparent.

10. The display substrate according to claim 1, wherein each metal line is connected to a signal line of the display functional layer through a lead on a side surface of the base substrate; or
each metal line is connected to a signal line of the display functional layer through a via hole penetrating the base substrate.

11. A display device, comprising the display substrate according to claim 1.

12. A method for forming a display substrate, comprising:
providing a base substrate;
forming a display functional layer on a first side surface of the base substrate, wherein the display functional layer comprises an encapsulation layer;
forming a plurality of metal lines on a second side surface of the base substrate, a first gap being provided between adjacent metal lines, and the first side surface being opposite to the second side surface;
wherein a first orthographic projection of the encapsulation layer onto the base substrate and a second orthographic projection of the first gap on the base substrate at least partially do not overlap each other, and/or, a light-shielding layer is formed at a side of the encapsulation layer facing the metal lines, the light-shielding layer is located on the first side surface of the base substrate, and a third orthographic projection of the light-shielding layer onto the base substrate at least partially overlaps the second orthographic projection.

13. The method for forming the display substrate according to claim 12, wherein the light-shielding layer and a gate metal layer of the display functional layer are formed through a single patterning process.

14. The method for forming the display substrate according to claim 12, wherein the forming the encapsulation layer comprises:
etching the encapsulation layer to form a plurality of hollowed-out regions, wherein the second orthographic projection falls within a fourth orthographic projection of each hollowed-out region onto the base substrate.

15. The display device according to claim 11, wherein the third orthographic projection fully coincides with the second orthographic projection.

16. The display device according to claim 11, wherein the light-shielding layer and a gate metal layer of the display functional layer are arranged at a same layer and made of a same material.

17. The display device according to claim 11, wherein the encapsulation layer comprises a plurality of hollowed-out regions, and the second orthographic projection falls within a fourth orthographic projection of each hollowed-out region onto the base substrate.

18. The display device according to claim 17, wherein the fourth orthographic projection does not overlap an orthographic projection of a metal layer on the first side surface of the base substrate onto the base substrate.

19. The display device according to claim 11, wherein the metal lines are fan-out area lines, a line width of each metal line is 60 μm to 80 μm, and a spacing between adjacent metal lines is 27 μm to 47 μm.

20. The display device according to claim 11, wherein the display substrate comprises:
a buffer layer located on the first side surface of the base substrate;
a gate insulation layer located at one side of the buffer layer away from the base substrate;
an interlayer insulation layer located at one side of the gate insulation layer away from the base substrate;
a planarization layer located at one side of the interlayer insulation layer away from the base substrate;
a passivation layer located at one side of the planarization layer away from the base substrate;
the encapsulation layer located at one side of the passivation layer away from the base substrate; and
a light-emitting element located at one side of the encapsulation layer away from the base substrate.
